(19) United States
(12) Patent Application Publication
(10) Pub. No.: US 2013/0269766 A1
(43) Pub. Date: Oct. 17, 2013

(54) INVERTED ORGANIC SOLAR CELL AND METHOD OF MANUFACTURING THE SAME

(71) Applicant: SAMSUNG ELECTRONICS CO., LTD., Suwon-si (KR)

(72) Inventors: Jong-jin PARK, Hwaseong-si (KR); Jae-hyun HUR, Yongin-si (KR)

(73) Assignee: SAMSUNG ELECTRONICS CO., LTD., Suwon-si (KR)

(21) Appl. No.: 13/724,330

(22) Filed: Dec. 21, 2012

(30) Foreign Application Priority Data
Apr. 17, 2012 (KR) 10-2012-0039972

(51) Int. Cl. H01L 51/42; H01L 51/00

(52) U.S. Cl. CPC H01L 51/4213; H01L 51/0002; B82Y 20/00
USPC 136/256; 438/82; 977/948; 977/892

(57) ABSTRACT

An inverted organic solar cell including a fiber type substrate, a cathode layer formed on the fiber type substrate, an electron transport layer comprising nanorods formed on the cathode layer, a photoactive layer formed on the electron transport layer, a hole transport layer formed on the photoactive layer, and an anode layer formed on the hole transport layer.

### CROSS-REFERENCE TO RELATED APPLICATIONS

This application claims the benefit of Korean Patent Application No. 10-2012-0039972, filed on Apr. 17, 2012, in the Korean Intellectual Property Office, the disclosure of which is incorporated herein in their entirety by reference.

### BACKGROUND

1. Field

The present disclosure relates to an inverted organic solar cell, and, more particularly, to a fiber-based inverted organic solar cell and a method of manufacturing the same.

2. Description of the Related Art

Many developments for organic solar cells are in progress thanks to the processability, flexibility, and easiness of implementing large-areas, which possibly lead to low-cost solar cells.

It is customary for a general organic solar cell to consist of an anode formed of a common transparent conductive oxide, a metal cathode having a low work function, and a photoactive layer of an organic compound disposed between the anode and cathode. However, with this structure, the metal cathode having the low work function tends to be easily oxidized, thus increasing serial resistance on an interfacial surface between the metal and the photoactive layer, and deteriorating the performance of the organic solar cell. An inverted organic solar cell has been introduced to address the problem.

In an inverted structure, metal having a high work function is used for the anode for collecting holes while indium tin oxide (ITO) is used for the cathode for collecting electrons. Although the inverted organic solar cell has an improved lifespan and reliability as compared to the non-inverted organic solar cell, there is a need for inverted organic solar cells which have higher quantum efficiency (QE) and flexibility.

### SUMMARY

Exemplary embodiments provide inverted organic solar cells having higher efficiency and flexibility than conventional inverted organic solar cells.

Exemplary embodiments further provide methods of manufacturing the inverted organic solar cells having the higher efficiency and flexibility.

Additional aspects will be set forth in part in the description which follows and, in part, will be apparent from the description, or may be learned by practice of the presented exemplary embodiments.

According to an aspect of, an inverted organic solar cell includes a fiber type substrate; a cathode layer formed on the fiber type substrate; an electron transport layer including nanorods formed on the cathode layer; a photoactive layer formed on the electron transport layer; a hole transport layer formed on the photoactive layer; and an anode layer formed on the hole transport layer.

The fiber type substrate may include glass fiber, polymer fiber or fiber reinforced plastic (FRP).

The cathode layer may include ITO, AZO, IZO, GZO, ITO—Ag—ITO, ITO—Cu—ITO, AZO—Ag—AZO, GZO—Ag—GZO, IZO—Ag—IZO or IZTO—Ag—IZTO.

The electron transport layer may include at least one compound selected from the compounds ZnO, SnO, SnO₂, In₂O₃, Cs₂CO₃, or a mixture of two or more of the compounds.

The nanorods of the electron transport layer may be arranged upwardly from the cathode layer.

Each of the nanorods of the electron transport layer may have a diameter in a range from approximately 10 nm to approximately 300 nm.

Each of the nanorods of the electron transport layer may be approximately 30 nm to approximately 2 μm long.

A gap between the nanorods of the electron transport layer may be approximately 1 nm to approximately 100 nm.

The photoactive layer may have a bulk heterogeneous junction (BHJ) structure of donor and acceptor areas.

A donor material of the donor area may include P3HT(poly(3-hexylthiophene), PCDTBT(poly[N-9″-hepta-decanyl-2,7-carbazole-alt-5,5-(4′,7′-di-2-thienyl-2′,1′,3′-benzothiadiazole)], MEH-PPV(poly[2-methoxy-5-(2′-ethylhexyloxy)-p-phenylene vinylene]) or MDMOPPV(poly[2-methoxy-5-3(3,7-dimethyloctyloxy)-1-4-phenylene vinylene).

An acceptor material may include C₆₀, PCBM ([6,6]-phenyl-C₆₁-butyric acid methyl ester), perylene, PTCBI (3,4,9,10-perylenetetracarboxylic-bis-benzimidazole) or DPP (dihydropyrrolo[3,4-c]pyrrole).

The photoactive layer may have a bulk heterogeneous junction (BHJ) structure of P3HT:PCBM, PCDTBT:PCBM or P3HT:DPP.

A domain size of the donor and acceptor areas may be about 10 nm.

The hole transport layer may include MoO₃, V₂O₅, NiO or CrOₓ.

The anode layer may include Ag, Ni, Au or Co.

According to another aspect, a method of manufacturing an inverted organic solar cell includes providing a fiber type substrate; forming a cathode layer on the fiber type substrate; forming an electron transport layer including nanorods on the cathode layer; forming a photoactive layer including a bulk heterogeneous junction (BHJ) structure on the electron transport layer; forming a hole transport layer on the photoactive layer; and forming an anode layer on the hole transport layer.

The fiber type substrate may include glass fiber, polymer fiber or fiber reinforced plastic (FRP).

The forming of the electron transport layer including nanorods may include forming a seed layer of transient metal oxide on the cathode layer; and growing from the seed layer the transient metal oxide as the nanorods via a hydrothermal growth process.

The transient metal oxide may include at least one compound selected from the compounds ZnO, SnO, SnO₂, In₂O₃, Cs₂CO₃, or a mixture of two or more of the compounds.

The forming of the photoactive layer may include dip-coating the fiber type substrate having the electron transport layer formed thereon with a mixed solution of donor and acceptor materials; and performing thermal annealing or solvent annealing on the dip-coated fiber type substrate.

### BRIEF DESCRIPTION OF THE DRAWINGS

These and/or other aspects will become apparent and more readily appreciated from the following description of the exemplary embodiments, taken in conjunction with the accompanying drawings of which:

FIG. 1A is a cross sectional view in the length direction of a fiber of an inverted organic solar cell, according to an exemplary embodiment;

FIG. 1B is a cross sectional view in the direction perpendicular to the length direction of the fiber of the inverted organic solar cell, according to an exemplary embodiment;

FIG. 2 is an energy band diagram of the inverted organic solar cell, according to an exemplary embodiment;

FIG. 3 is a diagram schematically illustrating flows of electrons and holes within a bulk heterojunction (BHJ) photoactive layer, according to an exemplary embodiment;

FIGS. 4A to 4F are cross sectional views sequentially illustrating a process of manufacturing the inverted organic solar cell, according to an exemplary embodiment; and

FIGS. 5A to 5D are atomic force microscopy (AFM) images of layers having BHJ structures of P3HT:PCBM obtained from Examples 5 to 8, respectively.

### DETAILED DESCRIPTION

Reference will now be made in detail to exemplary embodiments, examples of which are illustrated in the accompanying drawings, wherein like reference numerals refer to the like elements throughout. In this regard, the present exemplary embodiments may have different forms and should not be construed as being limited to the descriptions set forth herein. Accordingly, the exemplary embodiments are merely described below, by referring to the figures, to explain aspects of the present description.

An inverted organic solar cell according to an exemplary embodiment will now be described in detail.

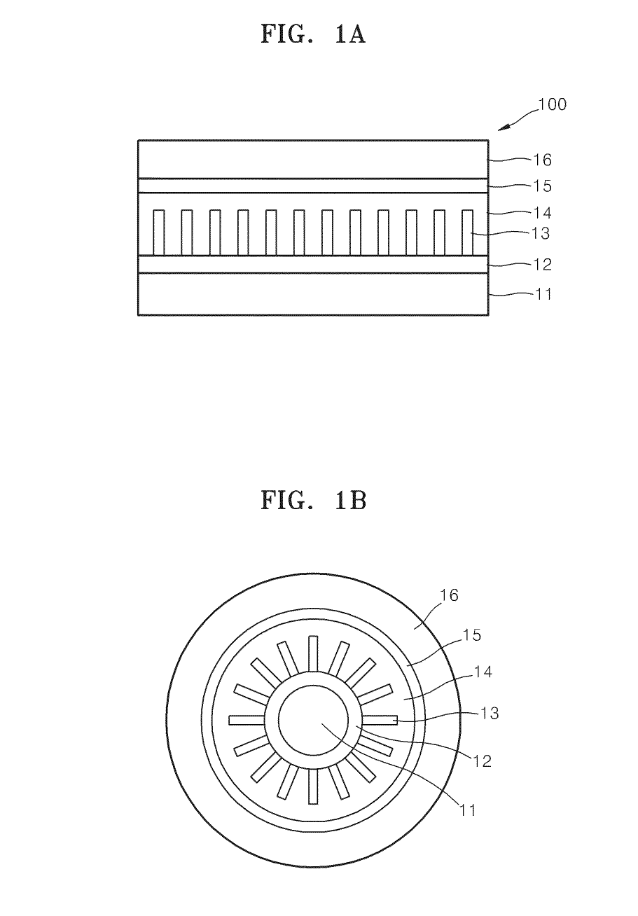

FIG. 1A is a cross sectional view in the length direction of a fiber of an inverted organic solar cell, according to an exemplary embodiment, and FIG. 1B is a cross sectional view in the direction perpendicular to the length direction of the fiber of the inverted organic solar cell. Referring to FIGS. 1A and 1B, on a fiber type substrate 11, there are a cathode layer 12, an electron transport layer 13, a photoactive layer 14, a hole transport layer 15, and an anode layer 16 formed in sequence.

The fiber type substrate 11 is made of a transparent fiber, e.g., a glass fiber, a polymer fiber, a Fiber Reinforced Plastic (FRP) fiber, etc. Since the substrate 11 is transparent, light may be efficiently transmitted to the photoactive layer 14 through the substrate 11. In addition, since the substrate 11 is of a fiber type, the inverted organic solar cell 100 may be weaved to be used as a power supply part for a fiber based device. The fiber type substrate 11 may be in the range of about 1-500 μm in diameter.

The cathode layer 12 may be made of a transparent conductive oxide. The transparent conductive oxide for the cathode layer 12 may be, for example, ITO, AZO, IZO, GZO, ITO—Ag—ITO, ITO—Cu—ITO, AZO—Ag—AZO, GZO—Ag—GZO, IZO—Ag—IZO or IZTO—Ag—IZTO. The cathode layer 12 may be in the range of about 10 nm-3 μm in thickness.

The electron transport layer 13 may consist of nanorods of transient metal oxide, which are arranged upwardly on the cathode layer 12. Being arranged upwardly refers to a configuration in which the cross sections of the nanorods that cover their diameters face upward from the cathode layer 12. The transient metal oxide of the electron transport layer 13 may be made of, for example, at least one compound selected from the compounds ZnO, SnO, Cs₂CO₃, In₂O₃, SnO₂, or a mixture of two or more of these compounds. In an exemplary embodiment, the diameter of each of the nanorods of the electron transport layer 13 is in a range of approximately 10 nm-300 nm, the length of the nanorods is in a range of approximately 30 nm-2 μm, and a gap between the nanorods may be in a range of approximately 1 nm-100 nm. Dimensions of the nanorods within such ranges may help to prevent recombination of charges and to facilitate the charges to be efficiently transmitted to an electrode. It is understood that the diameter and length of the nanorods and gap between the nanorads are not limited to these ranges.

With the electron transport layer 13 consisting of the nanorods arranged upwardly, a contact area between the electron transport layer 13 and the photoactive layer 14 may increase and the movement path of electrons may get shorter, thus improving an efficiency of electron transmission.

The photoactive layer 14 may have a bulk heterojunction (BHJ) structure (also referred to as a bulk heretogeneous junction (BHJ) structure) of donor and acceptor areas or a bilayer structure of donor and acceptor layers.

In the case of the BHJ structure, a donor material of the donor area is made of an n-type semiconductor organic compound. The donor material may be, e.g., poly(para-phenylene vinylene) (PPV) based, polythiophene (PT) based, or polyflourene (PF) based semiconductor polymers. Specifically, the donor material may be P3HT (poly(3-hexylthiophene), PCDTBT (poly[N-9″-hepta-decanyl-2,7-carbazole-alt-5,5-(4′,7′-di-2-thienyl-2′,1′,3′-benzothiadiazole)), MEH-PPV (poly[2-methoxy-5-(2′-ethylhexyloxy)-p-phenylene vinylene)) or MDMOPPV (poly[2-methoxy-5-3(3,7-dimethyloctyloxy)-1-4-phenylene vinylene), but is not limited thereto. An acceptor material of the acceptor area may be a p-type semiconductor organic compound. The acceptor material may be, e.g., C₆₀, PCBM ([6,6]-phenyl-C₆₁-butyric acid methyl ester), perylene, PTCBI (3,4,9,10-perylenetetracarboxylic-bis-benzimidazole) or DPP (dihydropyrrolo[3,4-c]pyrrole), but is not limited thereto. A pair of donor: acceptor materials that form the BHJ of the photoactive layer 14 may be, for example, P3HT: PCBM, PCDTBT:PCBM, or P3HT:DPP, but are not limited thereto.

A size of a domain of the donor area and the acceptor area may be in the range of about 5-30 nm, about 5-20 nm, or about 10 nm. The size of the domain in such a range is similar to an exciton diffusion length, thus improving a movement efficiency of holes and electrons separated from the exciton toward the cathode and the anode, respectively. It is understood that the size of the domain of the donor area and the acceptor area is not limited thereto, and may also be other sizes.

In the case of the bilayer structure, the donor material of the donor layer may be made of any of the same compounds or materials as the compounds or materials described above as the donor material in the case of the BHJ structure. Similarly, in the case of the bilayer structure, the acceptor material of the acceptor layer may be made of any of the same compounds or materials as the compounds or materials described above as the acceptor material in the case of the BHJ structure.

The photoactive layer 14 may be about 90 nm-2.2 μm thick. The photoactive layer 14 having a thickness in such a range may increase an amount of light absorption, and thus charge movement toward the electron transport layer 13 and the hole transport layer 15 may be efficiently made. It is understood that the photactive layer 14 is not limited thereto, and may have different thicknesses.

The hole transport layer 15 may comprise transient metal oxide. The hole transport layer 15 may be formed of e.g., MoO₃, V₂O₅, NiO or CrOₓ. The hole transport layer 15 may be about 0.1 nm-10 nm in thickness, although is not limited to this thickness range.

The anode layer 16 may be formed of metal having a high work function. For example, the anode layer 16 may be made of metal, such as, Ag, Ni, Au or Co, or another metal or material whose work function is in the range of about 4-5.5 eV. The anode layer 16 may be about 10 nm-3 μm in thickness, although is not limited to this thickness range.

Although, in FIGS. 1A and 1B, the inverted organic solar cell 100 is shown to have the cathode layer 12, the electron transport layer 13, the photoactive layer 14, the hole transport layer 15, and the anode layer 16 formed on the entire surface of the fiber type substrate 11, the cathode layer 12, the electron transport layer 13, the photoactive layer 14, the hole transport layer 15, and the anode layer 16 may alternatively be formed on a partial surface of the fiber type substrate 11. For example, all or some of the cathode layer 12, the electron transport layer 13, the photoactive layer 14, the hole transport layer 15, and the anode layer 16 may be formed on either an upper half or a lower half of a cylinder of the fiber type substrate 11.

Also, according to other exemplary embodiments, the stacking order of the inverted organic solar cell 100 may differ from the stacking order shown in FIGS. 1A and 1B. For example, the anode layer, the hole transport layer, the photoactive layer, the electron transport layer and the cathode layer may be formed in sequence on the fiber type substrate 11.

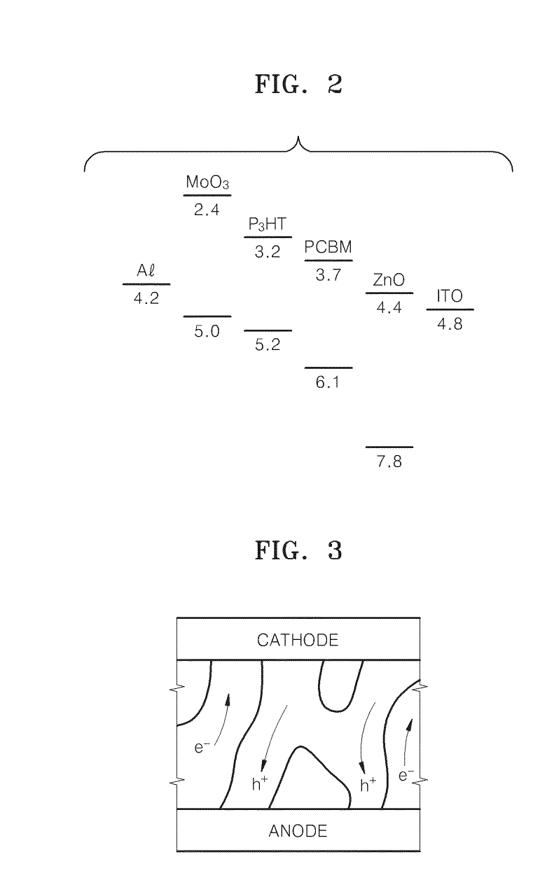

FIG. 2 is an energy band diagram of the inverted organic solar cell, according to an exemplary embodiment. Specifically, the inverted organic solar cell in connection with FIG. 2 has a stacking structure of a glass fiber (for the substrate)/ITO (for the cathode layer)/ZnO (for the electron transport layer)/P3HT:PCBM (for the photoactive layer)/MoO₃ (for the hole transport layer)/Al (for the anode layer). Referring to FIG. 2, electrons generated in the photoactive layer of P3HT:PCBM move along a step type conduction band to the ITO layer via a ZnO layer, while holes generated in the photoactive layer move along a step type valence band to the Al layer via the MoO₃ layer. Meanwhile, since the valence band edge of the ZnO layer has a much lower level than a HOMO (highest occupied molecular orbital) level of the P3HT and PCBM layers, the ZnO layer may prevent holes from being transferred to the ITO layer from the photoactive layer. Furthermore, the MoO₃ layer has a small electron affinity, which leads to intercepting the flow of electrons, thus improving the transfer of holes to the Al layer.

FIG. 3 is a diagram schematically illustrating flows of electrons and holes within the BHJ photoactive layer, according to an exemplary embodiment. Referring to FIG. 3, in the BHJ layer, there are donor areas and acceptor areas arbitrarily mixed. Here, electrons move along the donor areas toward the cathode while holes move along the acceptor areas toward the anode. In this exemplary embodiment, the donor areas are made of n-type semiconductor materials, and the acceptor areas are made of p-type semiconductor materials. In a case that sizes of the donor area and the acceptor area within the BHJ layer are shorter than the exciton diffusion length, an efficiency of moving electrons and holes separated from the exciton toward the cathode and the anode, respectively, may be improved.

A method of manufacturing an inverted organic solar cell according to an exemplary embodiment will now be described in detail.

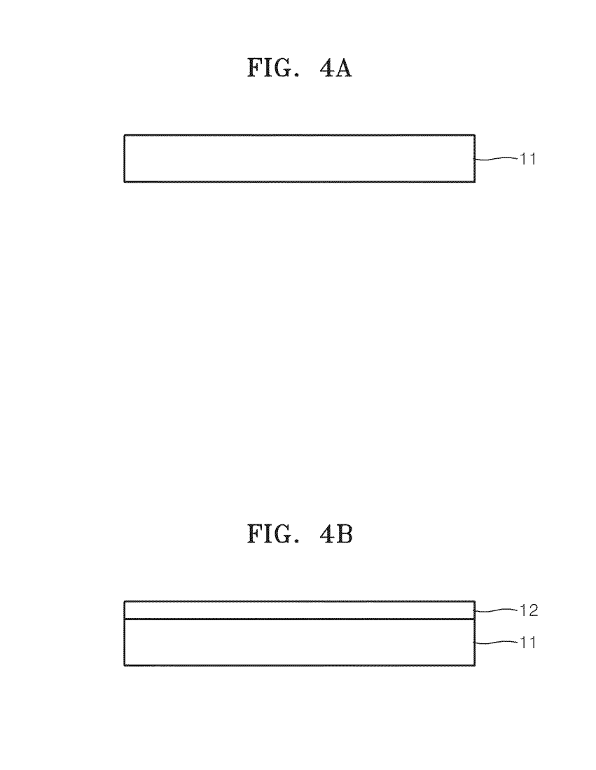

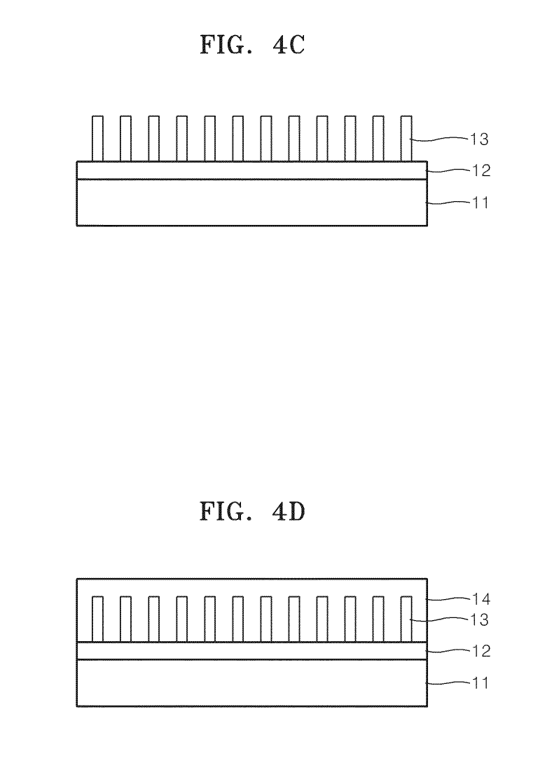

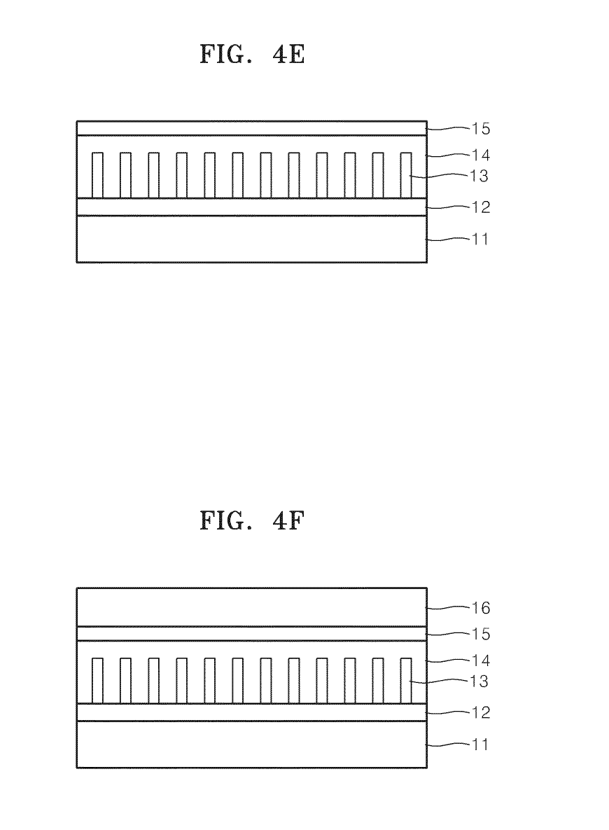

FIGS. 4A to 4F are cross sectional views sequentially illustrating a process of manufacturing the inverted organic solar cell, according to an exemplary embodiment.

Referring to FIG. 4A, the fiber type substrate 11 is first provided. The fiber type substrate 11 uses a fiber made of a transparent material, e.g., a glass fiber, a polymer fiber, a Fiber Reinforced Plastic (FRP) fiber, etc. The fiber type substrate 11 may be about 1-500 μm in diameter, although is not limited thereto.

Referring to FIG. 4B, the cathode layer 12 is formed on the fiber type substrate 11. The cathode layer 12 is made of transparent conductive oxide, such as ITO, AZO, IZO, GZO, ITO—Ag—ITO, ITO—Cu—ITO, AZO—Ag—AZO, GZO—Ag—GZO, IZO—Ag—IZO, IZTO—Ag—IZTO, etc. The cathode layer 12 may be formed by using pulse laser deposition, chemical vapor deposition (CVD), or an RF magnetron sputtering method. The cathode layer 12 may be about 10 nm-3 μm in thickness, although is not limited thereto.

Referring to FIG. 4C, the electron transport layer 13 is formed on the cathode layer 12. The electron transport layer 13 may be formed to be in an array of nanorods using transient metal oxide. The electron transport layer 13 may be made of, for example, ZnO, SnO, Cs₂CO₃, TiO₂, ZrO₂, etc., but is not limited thereto. The nanorods of the electron transport layer 13 may be grown from a seed layer (not shown) by a hydrothermal growth process, with the seed layer being made of the transient metal oxide and being formed on the cathode layer 12. The seed layer may be formed by an atomic layer deposition (ALD) technique, for example. The nanorods of the electron transport layer 13 may be grown from the surface of the cathode layer 12 upwardly in a radial manner. Here, the nanorods of the electron transport layer 13 may be formed, such that the diameter and the length of each of the nanorods may be in a range of about 10 nm-300 nm and about 30 nm-2 μm, respectively, and the gap between the nanorods may be in a range of about 1 nm-100 nm, although is not limited thereto.

Referring to FIG. 4D, the photoactive layer 14 may be formed on the electron transport layer 13. The photoactive layer 14 may be formed to have a bilayer structure or a BHJ structure.

In the case of having the bilayer structure, the photoactive layer 14 may be formed by sequentially dip-coating a donor material and an acceptor material on the electron transport layer 13.

In the case of having the BHJ structure, the photoactive layer 14 may be formed by dip-coating a mixture of the donor and acceptor materials on the electron transport layer 13 and then annealing. Specifically, a preliminary photoactive layer (not shown) is formed on the electron transport layer 13 by dipping the substrate 11 having the cathode layer 12 and the electron transport layer 13 formed thereon in a solution of the mixed donor and acceptor materials. After that, via thermal annealing or solvent annealing, the donor and acceptor materials in the preliminary photoactive layer are phase-separated, to form the photoactive layer 14 having the BHJ structure.

The donor material may include an n-type semiconductor organic compound, e.g., a poly(para-phenylene vinylene) (PPV) based, polythiophene (PT) based, or polyflourene (PF) based semiconductor polymer. Specifically, the donor material may include P3HT (poly(3-hexylthiophene), PCDTBT (poly[N-9″-hepta-decanyl-2,7-carbazole-alt-5,5-(4′,7′-di-2-thienyl-2′,1′,3′-benzothiadiazole)), MEH-PPV (poly[2-methoxy-5-(2′-ethylhexyloxy)-p-phenylene vinylene)) or MDMOPPV (poly[2-methoxy-5-3(3,7-dimethyloctyloxy)-1-4-phenylene vinylene), but is not limited thereto.

The acceptor material may include a p-type semiconductor organic compound, e.g., C₆₀, PCBM ([6,6]-phenyl-C₆₁-butyric acid methyl ester), perylene, PTCBI (3,4,9,10-perylenetetracarboxylic-bis-benzimidazole) or DPP (dihydropyrrolo[3,4-c]pyrrole), but is not limited thereto. A pair of donor:acceptor materials that form the BHJ of the photoactive layer 14 may include, for example, P3HT: PCBM, PCDTBT:PCBM, or P3HT:DPP, but are not limited thereto.

In the process of forming the BHJ structure, as a solvent for solving the donor and acceptor materials, various types of chemicals may be used, e.g., chloroform (CHCl₃), dichlorobenzene(DCB), or dimethylformamide (DMF). A solvent used for the solvent annealing may be a solvent of the mixed solution of the donor and acceptor materials, but is not limited thereto.

In the process of forming the BHJ structure, the thermal annealing or the solvent annealing may be performed at a temperature of about 90-160° C.

Referring to FIG. 4E, the hole transport layer 15 is formed on the photoactive layer 14. The hole transport layer 15 may be made of transition metal oxide, such as, MoO₃, V₂O₅, NiO or CrOₓ. Here, the hole transport layer 15 may be formed by using thermal evaporation, pulse laser evaporation, chemical vapor deposition, or RE magnetron sputtering. The hole transport layer 15 may be formed to be about 0.1 nm-10 nm thick, although is not limited thereto.

Referring to FIG. 4F, the anode layer 16 is formed on the hole transport layer 15. The anode layer 16 may be formed by, e.g., thermal depositing or chemical vapor deposition (CVD) of a metal, such as, Ag, Ni, or Au whose work function is high. The anode layer 16 may be formed to be about 10 nm-3 μm thick, although is not limited thereto.

Although in this exemplary embodiment the cathode layer 12, the electron transport layer 13, the photoactive layer 14, the hole transport layer 15, and the anode layer 16 are formed on the entire surface of the fiber type substrate 11, as shown in FIG. 1B, which is formed according to the process as discussed above in connection with FIGS. 4A to 4F, the cathode layer 12, the electron transport layer 13, the photoactive layer 14, the hole transport layer 15, and the anode layer 16 may alternatively be formed on a partial surface of the fiber type substrate 11. For example, all or some of the cathode layer 12, the electron transport layer 13, the photoactive layer 14, the hole transport layer 15, and the anode layer 16 may be formed on either an upper half or a lower half of a cylinder of the fiber type substrate 11.

### Example 1

An organic chemical that existed on the surface of a glass fiber substrate was removed by having the glass fiber substrate, which was about 30 mm in diameter and 50 mm long, go through piranha cleaning with a mixed solution of sulfuric acid and hydrogen peroxide at a 3:1 volume ratio for 10 minutes at 80° C.

By using the CVD technique, ITO was deposited 150 nm thick on a half side of the glass fiber substrate. The ITO deposited on the glass fiber substrate was cleansed with acetone, was subjected to ultrasonication in isopropyl alcohol, was cleansed with DI water, and then was dried in a vacuum oven for 30 minutes at 100° C.

A 10 nm thick ZnO seed layer was deposited on the ITO coated film via the ALD process. Next, ZnO nanorods were grown from the ZnO seed layer via a hydrothermal growth process using 0.025 M zinc nitrate dehydrate and 0.025 M hexamethylenetetramine. The ZnO nanorods were grown from the ITO surface in a radial manner, forming unevenness. The grown ZnO nanorods were rinsed with deionized water, and then dried again in the vacuum oven. Here, the ZnO nanorods were formed to be about 90-170 nm long.

The glass fiber substrate having the ZnO nanorods formed thereon was submerged into a solution obtained by using a chloroform solvent to mix P3HT and PCBM at a 1:4 mass ratio for about 15 minutes, and then went through thermal annealing in an N₂ atmosphere for 30 minutes at 90° C. As such, the photoactive layer having the BHJ structure of P3HT: PCBM was formed.

A 5 nm thick MoO₃ and a 100 nm thick Al were sequentially formed on the P3HT:PCBM photoactive layer via thermal evaporation.

### Example 2

The organic solar cell was manufactured via the same process as Example 1, except that the P3HT:PCBM coated layer went through thermal annealing at 120° C. instead of 90° C.

### Example 3

The organic solar cell was manufactured via the same process as Example 1, except that the P3HT:PCBM coated layer went through thermal annealing at 150° C. instead of 90° C.

### Example 4

The organic solar cell was manufactured via the same process as Example 1, except that the P3HT:PCBM coated layer went through thermal annealing at 180° C. instead of 90° C.

Table 1 shows annealing temperatures, open circuit voltages, short current densities and optical conversion efficiencies of the organic solar cells of Examples 1 to 4.

TABLE 1

| | | | | Optical |
|---|---|---|---|---|
| | Annealing | Open circuit | Short current | conversion |
| | temperatures | voltages (V_{OC}) | densities | efficiencies |
| | (° C.) | (V) | (J_{SC}) (mA/cm²) | (%) |
| Example 1 | 90 | 0.69 | 1.82 | 0.42 |
| Example 2 | 120 | 0.54 | 3.52 | 0.71 |
| Example 3 | 150 | 0.61 | 4.28 | 1.02 |
| Example 4 | 180 | 0.54 | 3.09 | 0.62 |

Referring to Table 1, the case of the thermal annealing temperature being 150° C. showed the highest optical conversion efficiency. It seems that this is because in the case of the thermal annealing at 150° C., domain sizes of the phase-separated P3HT and PCBM are closest to the exciton diffusion length (−10 nm).

### Example 5

A bulk BHJ layer of P3HT: PCBM was formed by submerging a glass fiber substrate into a solution obtained by using the chloroform solvent to mix a 1:4 mass ratio of P3HT and PCBM for 15 minutes, and then having the resulting glass fiber go through thermal annealing in an N₂ atmosphere for 10 minutes at 150° C.

### Example 6

The BHJ layer of P3HT: PCBM was formed via the same process as Example 3 except that, in Example 6, the thermal annealing was performed for 20 minutes.

### Example 7

The BHJ layer of P3HT: PCBM was formed via the same process as Example 3, except that, in Example 7, the thermal annealing was performed for 30 minutes.

### Example 8

The BHJ layer of P3HT: PCBM was formed via the same process as Example 3, except that, in Example 8, the thermal annealing was performed for 60 minutes.

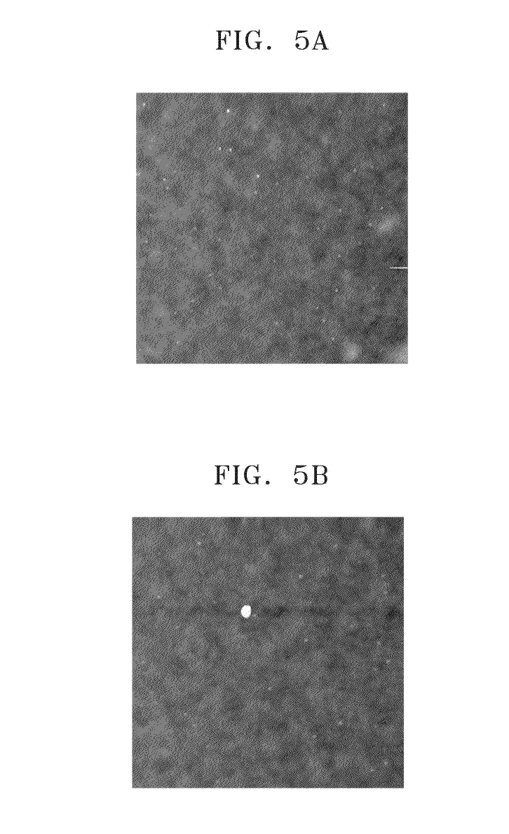

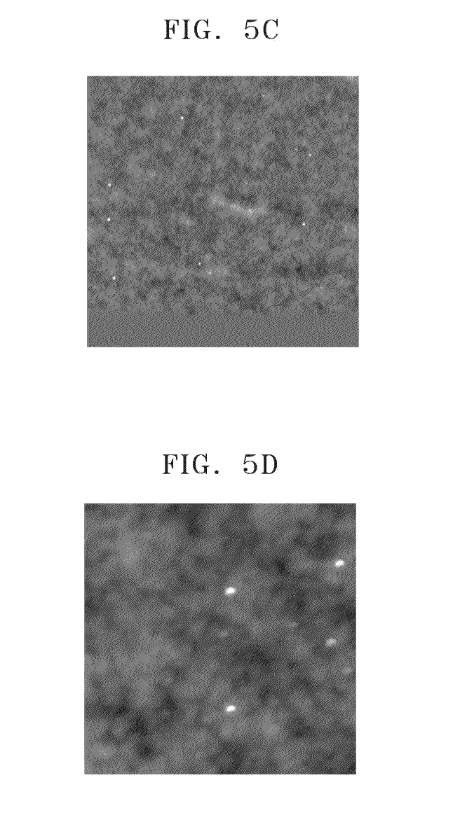

FIGS. 5A to 5D are atomic force microscopy (AFM) images of layers having P3HT: PCBM BHJ structures obtained from Examples 5 to 8, respectively, and Table 2 shows surface roughness measured from the AFM images of the same layers.

TABLE 2

| | Annealing | Annealing time | Surface roughness |
|---|---|---|---|
| | temperatures (° C.) | (minutes) | (RMS) (nm) |
| Example 5 | 150 | 10 | 0.56 ± 0.05 |
| Example 6 | 150 | 20 | 0.65 ± 0.10 |
| Example 7 | 150 | 30 | 1.15 ± 0.21 |
| Example 8 | 150 | 60 | 2.02 ± 0.41 |

Referring to FIGS. 5A to 5D, and Table 2, it can be seen that as the annealing time increases, the surface roughness of the BHJ layer increases. This is because as the annealing time increases, donor and acceptor areas formed by phase separation become larger.

As described above, according to exemplary embodiments of the present disclosure, the inverted organic solar cell may increase its flexibility by using a fiber-type substrate and may also increase transfer efficiency of electron carriers by using an electron transport layer formed of nanorods to increase device efficiency.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments. Furthermore, although a few exemplary embodiments have been shown and described, it will be appreciated by those skilled in the art that change may be made in these exemplary embodiments without departing from the principles and spirit of the invention, the range of which is defined in the appended claims and their equivalents.

What is claimed is:

1. An inverted organic solar cell, comprising,
a fiber type substrate;
a cathode layer formed on the fiber type substrate;
an electron transport layer comprising nanorods formed on the cathode layer;
a photoactive layer formed on the electron transport layer;
a hole transport layer formed on the photoactive layer; and
an anode layer formed on the hole transport layer.

2. The inverted organic solar cell of claim 1, wherein the fiber type substrate comprises glass fiber, polymer fiber or fiber reinforced plastic (FRP).

3. The inverted organic solar cell of claim 1, wherein the cathode layer comprises ITO, AZO, IZO, GZO, ITO—Ag—ITO, ITO—Cu—ITO, AZO—Ag—AZO, GZO—Ag—GZO, IZO—Ag—IZO or IZTO—Ag—IZTO.

4. The inverted organic solar cell of claim 1, wherein the electron transport layer comprises at least one compound selected from the compounds ZnO, SnO, SnO₂, In₂O₃, Cs₂CO₃, or a mixture of two or more of the compounds.

5. The inverted organic solar cell of claim 1, wherein the nanorods of the electron transport layer are arranged upwardly from the cathode layer.

6. The inverted organic solar cell of claim 1, wherein each of the nanorods of the electron transport layer has a diameter in a range from approximately 10 nm to approximately 300 nm.

7. The inverted organic solar cell of claim 1, wherein each of the nanorods of the electron transport layer is approximately 30 nm to approximately 2 μm long.

8. The inverted organic solar cell of claim 1, wherein a gap between the nanorods of the electron transport layer is approximately 1 nm to approximately 100 nm.

9. The inverted organic solar cell of claim 1, wherein the photoactive layer has a bulk heterogeneous junction (BHJ) structure of donor and acceptor areas.

10. The inverted organic solar cell of claim 9, wherein a donor material of the donor area comprises P3HT(poly(3-hexylthiophene), PCDTBT(poly[N-9″-hepta-decanyl-2,7-carbazole-alt-5,5-(4′,7′-di-2-thienyl-2′,1′,3′-benzothiadiazole)], MEH-PPV(poly[2-methoxy-5-(2′-ethylhexyloxy)-p-phenylene vinylene]) or MDMOPPV(poly[2-methoxy-5-3(3,7-dimethyloctyloxy)-1-4-phenylene vinylene).

11. The inverted organic solar cell of claim 9, wherein an acceptor material comprises C₆₀, PCBM ([6,6]-phenyl-C₆₁-butyric acid methyl ester), perylene, PTCBI (3,4,9,10-perylenetetracarboxylic-bis-benzimidazole) or DPP (dihydropyrrolo[3,4-c]pyrrole).

12. The inverted organic solar cell of claim 9, wherein the photoactive layer has a bulk heterogeneous junction (BHJ) structure of P3HT:PCBM, PCDTBT:PCBM or P3HT:DPP.

13. The inverted organic solar cell of claim 9, wherein a domain size of the donor and acceptor areas is about 10 nm.

14. The inverted organic solar cell of claim 1, wherein the hole transport layer comprises MoO₃, V₂O₅, NiO or CrOₓ.

15. The inverted organic solar cell of claim 1, wherein the anode layer comprises Ag, Ni, Au or Co.

16. A method of manufacturing an inverted organic solar cell, the method comprising:
providing a fiber type substrate;
forming a cathode layer on the fiber type substrate;
forming an electron transport layer comprising nanorods on the cathode layer;
forming a photoactive layer comprising a bulk heterogeneous junction (BHJ) structure on the electron transport layer;
forming a hole transport layer on the photoactive layer; and
forming an anode layer on the hole transport layer.

17. The method of manufacturing the inverted organic solar cell of claim 16, wherein the fiber type substrate comprises glass fiber, polymer fiber or fiber reinforced plastic (FRP).

18. The method of manufacturing the inverted organic solar cell of claim 16, wherein the forming of the electron transport layer comprising nanorods comprises:
forming a seed layer of transient metal oxide on the cathode layer; and
growing from the seed layer the transient metal oxide as the nanorods via a hydrothermal growth process.

19. The method of manufacturing the inverted organic solar cell of claim 16, wherein the transient metal oxide comprises at least one compound selected from the compounds ZnO, SnO, SnO₂, In₂O₃, Cs₂CO₃, or a mixture of two or more of the compounds.

20. The method of manufacturing the inverted organic solar cell of claim 16, wherein the forming of the photoactive layer comprises:
dip-coating the fiber type substrate having the electron transport layer formed thereon with a mixed solution of donor and acceptor materials; and
performing thermal annealing or solvent annealing on the dip-coated fiber type substrate.
